(19) United States
(12) Patent Application Publication
(10) Pub. No.: US 2023/0371275 A1
(43) Pub. Date: Nov. 16, 2023

(54) METHOD OF FORMING DIFFERENT TYPES OF MEMORY DEVICES

(71) Applicant: Taiwan Semiconductor Manufacturing Company, Ltd., Hsinchu (TW)

(72) Inventors: Yu-Jen Wang, Hsinchu (TW); Sheng-Huang Huang, Hsinchu City (TW); Harry-Hak-Lay Chuang, Hsinchu (TW); Hung Cho Wang, Taipei (TW); Ching-Huang Wang, Pingjhen City (TW); Kuo-Feng Huang, Hsinchu (TW)

(21) Appl. No.: 17/880,186

(22) Filed: Aug. 3, 2022

Related U.S. Application Data
(60) Provisional application No. 63/341,840, filed on May 13, 2022.

(51) Int. Cl. H01L 27/22; H01L 43/02; H01L 43/10; H01L 43/12

(52) U.S. Cl. CPC H01L 27/222; H01L 43/02; H01L 43/10; H01L 43/12

(57) ABSTRACT

A semiconductor device according to the present disclosure includes a first conductive feature and a second conductive feature in a first dielectric layer, a buffer layer over the first dielectric layer, a second dielectric layer over the buffer layer, a first bottom via extending through the buffer layer and the second dielectric layer, a second bottom via extending through the buffer layer and the second dielectric layer, a first bottom electrode disposed on the first bottom via, a second bottom electrode disposed on the second bottom via, a first magnetic tunnel junction (MTJ) stack over the first bottom electrode, and a second MTJ stack over the second bottom electrode. The first MTJ stack and the second MTJ stack have a same thickness. The first MTJ stack has a first width and the second MTJ stack has a second width greater than the first width.

### PRIORITY DATA

The present application claims the benefit of U.S. Provisional Application No. 63/341,840, filed May 13, 2022, herein incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Modern-day electronic devices contain volatile or non-volatile electronic memory to store data. Volatile memory stores data when it is powered, while non-volatile memory is able to retain stored data when power is removed. Magneto-resistive random-access memory (MRAM) is one promising candidate for a next generation non-volatile memory technology. MRAM devices may be configured differently to meet different design requirements. The different configurations may create challenges when different MRAM devices are integrated and fabricated in a single chip. Therefore, while existing MRAM integration schemes are generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming a semiconductor structure having different memory structures, according to one or more aspects of the present disclosure.

FIGS. 2-8 illustrate fragmentary cross-sectional views of a workpiece during a fabrication process according to the method of FIG. 1, according to one or more aspects of the present disclosure.

FIG. 9 is a schematic illustration of different memory structures being implemented in different regions of a single integrated circuit (IC) device, according to one or more aspects of the present disclosure.

FIG. 10 illustrates a flow chart of a method for forming a semiconductor structure having different memory structures, according to one or more aspects of the present disclosure.

FIGS. 11-17 illustrate fragmentary cross-sectional views of a workpiece during a fabrication process according to the method of FIG. 1, according to one or more aspects of the present disclosure.

FIG. 18 is a schematic illustration of different memory structures being implemented in different regions of a single integrated circuit (IC) device, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

A bit cell of a magneto-resistive random-access memory (MRAM) device includes a magnetic tunnel junction (MTJ) stack vertically arranged between two electrodes, usually a bottom electrode and a top electrode. The MTJ stack includes a pinned layer separated from a free layer by a tunnel barrier layer. The magnetic orientation of the pinned layer is static (i.e., fixed), while the magnetic orientation of the free layer is capable of switching between a parallel configuration and an anti-parallel configuration with respect to that of the pinned magnetic layer. The parallel configuration provides for a low resistance state that digitally stores data as a first bit value (e.g., a logical “0”). The anti-parallel configuration provides for a high resistance state that digitally stores data as a second bit value (e.g., a logical “1”). The switching between the two configurations provides two magnetic states of the MTJ stack. The magnetic state of the MTJ stack is set by application of a write current of appropriate amplitude and polarity, or read out by application of a read current to apply a voltage to a sense circuit. Depending on the resistance states of the bit cell, the voltage may be higher or lower.

In some implementations, the bit cell of an MRAM is controlled by a driving transistor disposed at the front-end-of-line (FEOL) level. The driving transistor includes a source feature, a drain feature, an active region between the source feature and the drain feature and a gate structure over the active region. When the bit cell is disposed in a frontside interconnect structure over the driving transistor, the top electrode is coupled to a bit line (BL) and the bottom electrode is coupled to one of the drain feature of the driving transistor through a series of island-like metal features and contact vias. A source line (SL) is electrically coupled to the source feature of the driving transistor. The gate structure of the driving transistor is coupled to a word line (WL). When the word line (WL) is selected by application of an enabling voltage, the driving transistor is turned on. The bit cell is coupled between the bit line (BL) and the source line (SL).

MRAM devices come in various flavors to suit different design needs. For example, flash-like (reflow) MRAM has good thermal stability and data stored therein is less likely to be lost after a reflow (heating) process. A reflow MRAM may have a response time less than 100 nano-seconds (ns). A RAM-like MRAM has short term non-volatile property and can be read or written at a faster speed using a relatively small current. A RAM-like MRAM has a faster response time, such as smaller than 20 ns. A non-volatile MRAM (NvMRAM) device has properties falling in between those of a reflow MRAM and RAM-like MRAM. It has good memory retention but is not required to operate at a relatively high temperature. An NvMRAM may have a response time less than 50 ns. An one-time-programmable (OTP) MRAM device is configured to be written only once by a writing voltage. The writing voltage is high enough to irreversibly break down the dielectric layers in the MTJ stack of the OTP MRAM. As a result, data stored in an OTP MRAM cannot be varied. These different MRAM devices have different configurations. For example, in some existing implementations, a reflow MRAM may have a thicker free layer to improve thermal stability. A RAM-like MRAM may have a thinner free layer to achieve fast response. However, forming free layers of different thicknesses on the same substrate may require additional photolithography steps and incur additional cost. There is a need to form different MRAM devices on a single IC with reasonable cost and yield.

The present disclosure provides single-IC MRAM integration schemes that allow different kinds of MRAM devices to be fabricated simultaneously on the same IC without substantial performance tradeoffs. To allow for simultaneous fabrication at a reasonable cost, the free layer in the MRAM devices in each of the single-IC MRAM integration schemes has a uniform thickness. The different thermal stability and response time requirements are met by implementing different MTJ critical dimensions (CDs). Because the switching of MRAM devices depends on current density, implementing MTJ stacks of different critical dimensions can vary current density and therefore response time. In some embodiments, the MTJ CD for a reflow MRAM is greater than that for an NvMRAM and the MTJ CD for an OTP MRAM is greater than that of a RAM-like MRAM or an NvMRAM. In one single-IC MRAM integration scheme, reflow-MRAMs, NvMRAMs and OTP MRAMs are integrated on one IC. In another single-IC MRAM integration scheme, RAM-like MRAMs, OTP MRAMs, and NvMRAMs are integrated on one IC.

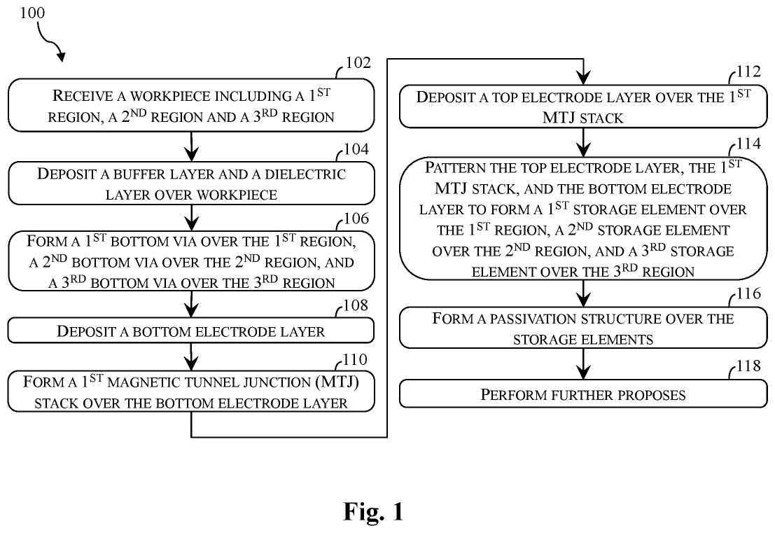

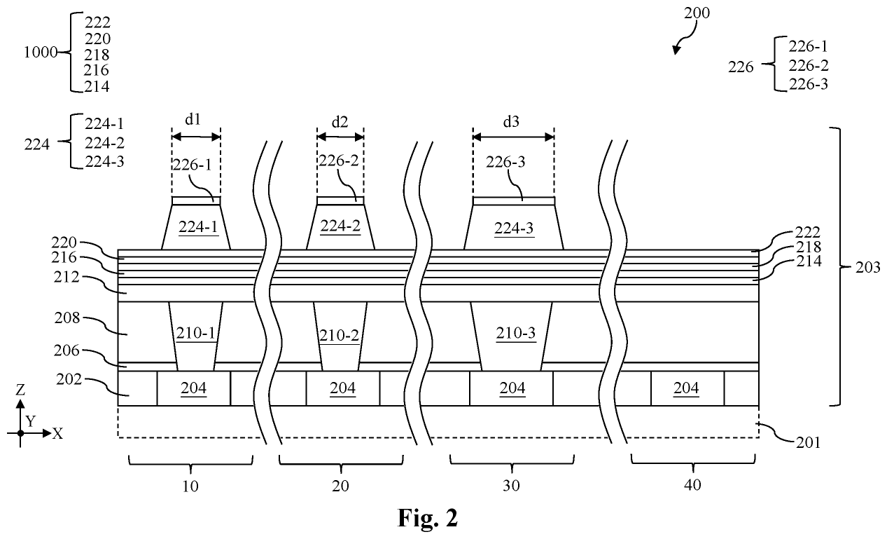

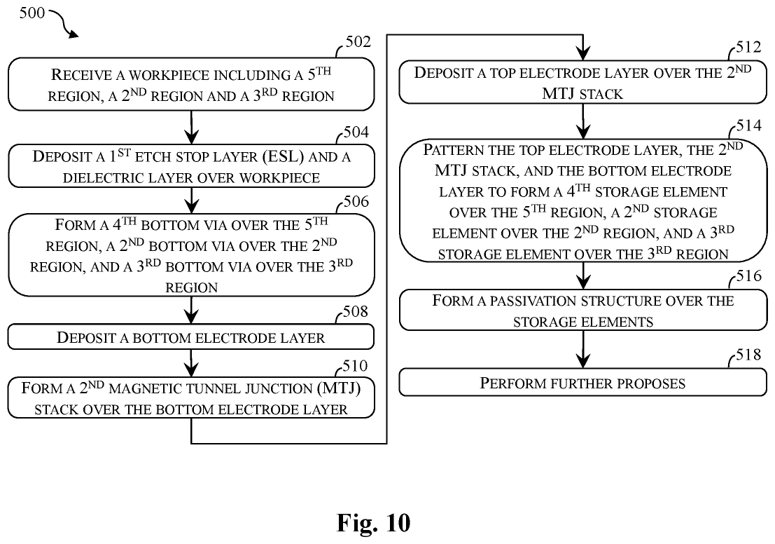

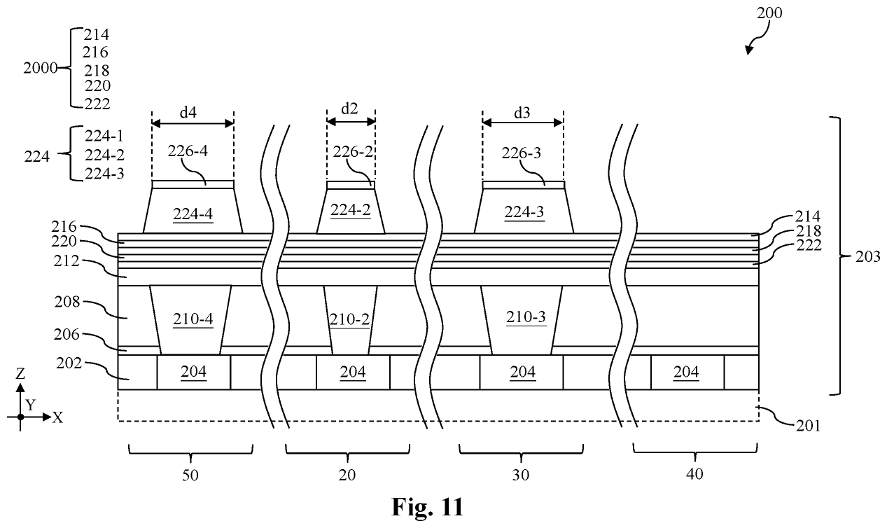

The various aspects of the present disclosure will now be described in more detail with reference to the figures. In that regard, FIG. 1 is a flowchart illustrating method 100 of forming an IC device structure according to embodiments of the present disclosure. Method 100 is described below in conjunction with FIGS. 2-8, which are fragmentary cross-sectional views of a workpiece 200 at different stages of fabrication according to embodiments of method 100. FIG. 10 is a flowchart illustrating method 500 of forming an IC device structure according to embodiments of the present disclosure. Method 500 is described below in conjunction with FIGS. 11-17, which are fragmentary cross-sectional views of a workpiece 200 at different stages of fabrication according to embodiments of method 500. Methods 100 and 500 are merely examples and are not intended to limit the present disclosure to what is explicitly illustrated in method 100 or 500. Additional steps may be provided before, during and after the method 100 or method 500, and some steps described can be replaced, eliminated, or moved around for additional embodiments of the method. Not all steps are described herein in detail for reasons of simplicity. Because the workpiece 200 will be fabricated into a semiconductor structure 200 or a semiconductor device 200 upon conclusion of the fabrication processes, the workpiece 200 may be referred to as the semiconductor structure 200 or the semiconductor device 200 as the context requires.

Referring to FIGS. 1 and 2, method 100 includes a block 102 where a workpiece 200 is received. The workpiece 200 includes a substrate 201 and an interconnect structure 203 over the substrate 201. Method 100 may be implemented to form memory devices or storage structures in one of about five (5) to about nineteen (19) metal layers (or metallization layers) in the interconnect structure 203. The interconnect structure 203 may be backside interconnect structure or a frontside interconnect structure. As will be described further below, the substrate 201 is formed of a semiconductor material and has undergone front-end-of-line (FEOL) processes. Such FEOL processes may form various transistors to serve different functions. For example, these various transistors may form a central processing unit (CPU), a graphics process unit (GPU), access transistors for memory devices. The transistors may be planar transistors or multi-gate transistors. A multi-gate device generally refers to a device having a gate structure, or portion thereof, disposed over more than one side of a channel region. Fin-like field effect transistors (FinFETs) and multi-bridge-channel (MBC) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. The channel region of an MBC transistor may be formed from nanowires, nanosheets, or other nanostructures and for that reasons, an MBC transistor may also be referred to as a nanowire transistor or a nanosheet transistor.

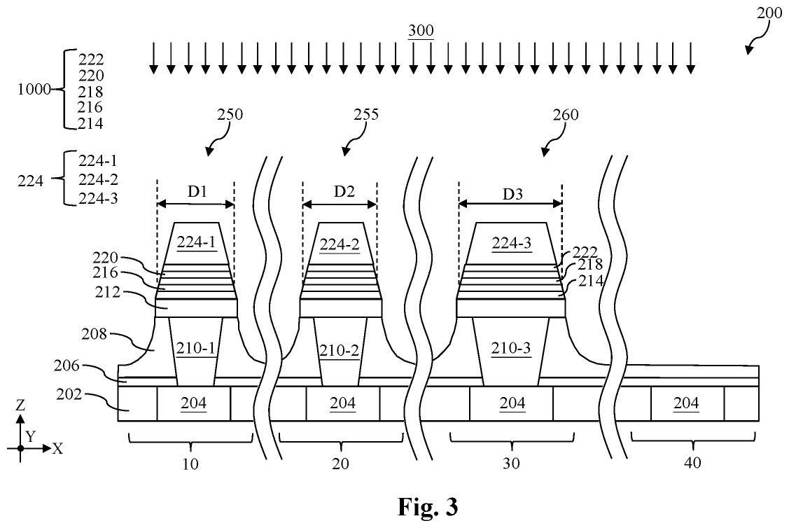

In some embodiments, the substrate 201 includes silicon (Si). Alternatively or additionally, substrate 201 includes another elementary semiconductor, such as germanium (Ge); a compound semiconductor, such as silicon carbide, gallium arsenide, gallium phosphide, indium phosphide, indium arsenide, and/or indium antimonide; an alloy semiconductor, such as silicon germanium (SiGe), GaAsP, AlInAs, AlGaAs, GalnAs, GaInP, and/or GaInAsP; or combinations thereof. In some implementations, the substrate 201 includes one or more group III-V materials, one or more group II-IV materials, or combinations thereof. In some implementations, the substrate 201 is a semiconductor-on-insulator substrate, such as a silicon-on-insulator (SOI) substrate, a silicon germanium-on-insulator (SGOI) substrate, or a germanium-on-insulator (GeOI) substrate. Semiconductor-on-insulator substrates can be fabricated using separation by implantation of oxygen (SIMOX), wafer bonding, and/or other suitable methods. Because method 100 is performed to a workpiece 200 to which FEOL processes have been performed to the substrate 201, the substrate 201 is only shown in dotted lines in FIG. 2 and is omitted from FIGS. 3-8.

While the interconnect structure 203 includes several metal layers, the memory devices/storage structures may be formed in one of the metal layers, such as a fourth metal layer (M4), a fifth metal layer (M5), or a sixth metal layer (M6). Because the interconnect structure 203 may be a front side interconnect structure or a back side interconnect structure, the memory devices/storage structures of the present disclosure may be formed in a fourth frontside metal layer, a fifth frontside metal layer, a sixth frontside metal layer, a fourth backside metal layer, a fifth backside metal layer, a sixth backside metal layer. Referring to FIG. 2, conductive features 204 in a first dielectric layer 202 represent a metal layer below the memory devices. The first dielectric layer 202 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The conductive features 204 may be metal lines and may include ruthenium (Ru), copper (Cu), nickel (Ni), cobalt (Co), or tungsten (W). In one embodiment, the conductive features 204 include copper (Cu). The conductive features 204 may include metal lines or contact vias.

Referring still to FIG. 2, the workpiece 200 includes a first region 10, a second region 20, a third region 30, and a fourth region 40. These regions may be adjacent to one another or may be spaced apart from one another. These different regions may have different arrangements with respect to memory devices. In some embodiments, the first region 10 may be a region for formation of RAM-like MRAMs, the second region 20 may be a region for formation of NvMRAMs, the third region 30 may be a region for formation of OTP MRAMs, and the fourth region 40 may be a region that is free of any MRAM structure.

Referring to FIGS. 1 and 2, method 100 includes a block 104 where a buffer layer 206 and a second dielectric layer 208 are deposited over the workpiece 200. The buffer layer 206 may include silicon carbide (SiC) or silicon oxycarbide (SiOC), which helps suppress electromigration of the conductive features 204. The second dielectric layer 208 may include silicon oxide. In one embodiments, the second dielectric layer 208 may include silicon-rich oxide (SRO) and is different from the first dielectric layer 202. As used herein, a silicon content in silicon-rich oxide is smaller than the silicon stoichiometric ratio in silicon dioxide. In this embodiment, the silicon content in the first dielectric layer 202 is greater than the silicon content in the second dielectric layer 208. The buffer layer 206 may be deposited using chemical vapor deposition (CVD). The second dielectric layer 208 may be deposited using low-pressure CVD (LPCVD) or CVD.

Referring to FIGS. 1 and 2, method 100 includes a block 106 where a first bottom via 210-1, a second bottom via 210-2 and a third bottom via 210-3 are formed over the first region 10, the second region 20, and the third region 30, respectively. While not explicitly shown in FIG. 2, operations at block 106 may include formation of via openings to expose the conductive features 204 and formation of the first bottom via 210-1, the second bottom via 210-2 and the third bottom via 210-3 in the via openings. Formation of the via openings includes a combination of photolithography processes and etch processes. In an example process, a hard mask layer is deposited over the second dielectric layer 208. A photoresist layer is deposited over the hard mask layer. The photoresist layer is then exposed to a patterned radiation transmitting through or reflected from a photo mask, baked in a post-exposure bake process, developed in a developer solution, and then rinsed, thereby forming a patterned photoresist layer. The patterned photoresist layer is then applied as an etch mask to etch the hard mask layer to form a patterned hard mask layer. The patterned hard mask layer is then applied as an etch mask to etch the second dielectric layer 208 and the buffer layer 206. The etch of the second dielectric layer 208 and the buffer layer 206 may be a dry etch process that includes use of argon (Ar), a fluorine-containing etchant (for example, SF₆, NF₃, CH₂F₂, CHF₃, C₄F₈, and/or C₂F₆), an oxygen-containing etchant, a chlorine-containing etchant (for example, Cl₂, CHCl₃, CCl₄, and/or BCl₃), a bromine-containing etchant (for example, HBr and/or CHBr₃), an iodine-containing etchant, or combinations thereof.

After the via openings are formed, a metal fill layer is deposited over the workpiece 200 to fill the via openings. The metal fill layer may include titanium nitride (TiN), ruthenium (Ru), copper (Cu), nickel (Ni), cobalt (Co), or tungsten (W). In one embodiment, the metal fill layer may include titanium nitride (TiN). The metal fill layer may be deposited using physical vapor deposition (PVD), CVD, electroless plating, electroplating, or a suitable method. After the deposition of the metal fill layer, the workpiece 200 is planarized using a chemical mechanical polishing (CMP) process remove the excess metal fill layer to expose the second dielectric layer 208. At this point, the first bottom via 210-1 is formed in the first region 10 to electrically and physically coupled to the conductive feature 204 in the first region 10; the second bottom via 210-2 is formed in the second region 20 to electrically and physically coupled to the conductive feature 204 in the second region 20; and the third bottom via 210-3 is formed in the third region 30 to electrically and physically coupled to the conductive feature 204 in the third region 30. It is noted that no bottom via is formed over the fourth region 40.

Referring to FIGS. 1 and 2, method 100 includes a block 108 where a bottom electrode layer 212 is deposited over the workpiece 200, including over the second dielectric layer 208, the first bottom via 210-1, the second bottom via 210-2, and the third bottom via 210-3. The bottom electrode layer 212 may be a single layer or a multi-layer. When the bottom electrode layer 212 is a single layer, it may include titanium nitride (TiN) or tantalum nitride (TaN). When the bottom electrode layer 212 is a multi-layer, it may include a tantalum nitride (TaN) layer and a titanium nitride (TiN) layer. The bottom electrode layer 212 may be deposited using PVD or CVD. The bottom electrode layer 212 is globally deposited over the workpiece 200, including over top surfaces of the first bottom via 210-1, the second bottom via 210-2, the third bottom via 210-3, and the second dielectric layer 208.

Referring to FIGS. 1 and 2, method 100 includes a block 110 where a first magnetic tunnel junction (MTJ) stack 1000 is deposited over the bottom electrode layer 212. The first MTJ stack 1000 includes a pinned layer 214 over the bottom electrode layer 212, a tunnel barrier layer 216 over the pinned layer 214, a free layer 218 over the tunnel barrier layer 216, a maintenance layer 220 over the free layer 218, and a capping layer 222 disposed over the maintenance layer 220. The pinned layer 214 may include a ferromagnetic material such as cobalt iron (CoFe), cobalt iron boron (CoFeB), or a cobalt-platinum (Co—Pt) alloy. In some alternative embodiments, the pinned layer 214 may include CoFeTa, NiFe, Co, CoFe, CoPt, an alloy of Ni, Co and Fe, platinum manganese (PtMn), iridium manganese (IrMn), rhodium manganese (RhMn), iron manganese (FeMn), or OsMn. The tunnel barrier layer 216 may be formed of a metal oxide selected from a group consisting of magnesium oxide (MgO), titanium oxide (TiO), aluminum titanium oxide (AlTiO), magnesium zinc oxide (MgZnO), aluminum oxide (AlO), zinc oxide (ZnO), zirconium oxide (ZrO), hafnium oxide (HfO), or magnesium tantalum oxide (MgTaO). In one embodiment, the tunnel barrier layer 216 is formed of magnesium oxide. The free layer 218 is formed of a ferromagnetic material and may include cobalt iron boron (CoFeB). The maintenance layer 220 may be formed of a metal oxide selected from a group consisting of magnesium oxide (MgO), titanium oxide (TiO), aluminum titanium oxide (AlTiO), magnesium zinc oxide (MgZnO), aluminum oxide (AlO), zinc oxide (ZnO), zirconium oxide (ZrO), hafnium oxide (HfO), or magnesium tantalum oxide (MgTaO). In one embodiment, the maintenance layer 220 may include magnesium oxide. The capping layer 222 may be optional and may include molybdenum (Mo) or ruthenium (Ru). The pinned layer 214, the tunnel barrier layer 216, the free layer 218, the maintenance layer 220, and the capping layer 222 may each be deposited using PVD, CVD, electro-plating, electro-less plating, or a suitable method. In some embodiments not explicitly shown in the figures, the capping layer 222 may be omitted and the first MTJ stack 1000 may only include the pinned layer 214, the tunnel barrier layer 216, the maintenance layer 220, and the free layer 218. A second MTJ stack 2000 will be described below along with an alternative method 500. The second MTJ stack 2000 has a stacking order that is inverse of that of the first MTJ stack 1000. It should be understood that method 100 can also be used to implement the second MTJ stack 2000 instead of the first MTJ stack 1000.

Referring to FIGS. 1 and 2, method 100 includes a block 112 where a top electrode layer 224 is deposited over the first MTJ stack 1000. The top electrode layer 224 may be a single layer or a multi-layer. When the top electrode layer 224 is a single layer, it may include titanium nitride (TiN) or tantalum nitride (TaN). When the top electrode layer 224 is a multi-layer, it may include a tantalum nitride layer and a titanium nitride layer. The top electrode layer 224 may be deposited using PVD or CVD. The top electrode layer 224 is globally deposited over the workpiece 200, including over the first MTJ stack 1000.

Referring to FIGS. 1, 2 and 3, method 100 includes a block 114 where the top electrode layer 224, the first MTJ stack 1000, and the bottom electrode layer 212 are patterned to form a first storage element 250 over the first region 10, a second storage element 255 over the second region 20, and a third storage element 260 over the third region 30. At block 114, photolithography processes and etch processes are performed to form the first storage element 250, the second storage element 255, and the third storage element 260. In an example process, a hard mask layer 226 is deposited over the workpiece 200, including over the top electrode layer 224. In some embodiments, the hard mask layer 226 may include silicon oxide, silicon nitride, or a combination thereof. In one embodiment, the hard mask layer 226 is formed of silicon oxide (e.g. tetraethylorthosilicate (TEOS) oxide) and may be deposited using spin-on coating or flowable CVD (FCVD). A photoresist layer is then deposited over the hard mask layer 226. The deposited photoresist layer is then exposed to a patterned radiation transmitting through or reflected from a photo mask, baked in a post-exposure bake process, developed in a developer solution, and then rinsed, thereby forming a patterned photoresist layer. As shown in FIG. 2, the patterned photoresist layer is then applied as an etch mask to etch the hard mask layer 226 to form a first hard mask pattern 226-1 over the first region 10, a second hard mask pattern 226-2 over the second region 20, and a third hard mask pattern 226-3 over the third region 30. These patterned hard mask patterns are then applied as an etch mask to etch the top electrode layer 224, the first MTJ stack 1000, the bottom electrode layer 212, and the second dielectric layer 208. The etching at block 114 may include an Ion beam etching (IBE) 300. When it comes to patterning of MTJ stacks, IBE may be more desirable than reactive ion etching (RIE) because IBE is less likely to introduce chemical impurities into the MTJ stack. Impurities may deteriorate performance of the storage element. The IBE 300 may use one or more noble gas ions such as Ar, Kr, Xe, and Ne generated with an RF or DC power. It should be understood that IBE typically includes rotating the workpiece 200.

In order to form memory devices with different device properties, the storage elements have different dimensions. It is observed that, given an identical MTJ stack, a storage element with a larger free layer exhibit better thermal stability than a storage element having a smaller free layer. Additionally, a storage element having a smaller free layer provides faster response time than a storage element having a larger free layer. In some embodiments where a storage elements has a circular shape when viewed along a vertical direction, a critical dimension (CD) of the storage element may refer to a diameter of the free layer. In some embodiments represented in FIG. 2, hard mask patterns of different dimensions are implemented to achieve different storage element diameters (or dimensions). As shown in FIG. 2, the first hard mask pattern 226-1 has a first dimension d1, the second hard mask pattern 226-2 has a second dimension d2, and the third hard mask pattern 226-3 has a third dimension d3. The first dimension d1 may be similar to the second dimension d2. The third dimension d3 is greater than either the first dimension d1 or the second dimension d2.

As shown in FIG. 3, the IBE 300 may result in tapered sidewalls such that each of the first storage element 250, the second storage element 255, and the third storage element 260 has a smaller top electrode dimension and a larger bottom element dimension. The first storage element 250 includes the first top electrode 224-1 formed from the top electrode layer 224. The second storage element 255 includes the second top electrode 224-2 formed from the top electrode layer 224. The third storage element 260 includes the third top electrode 224-3 formed from the top electrode layer 224. In some embodiments, the first storage element 250 may be characterized by a first MTJ dimension D1, which may be substantially similar to the dimension (or diameter) of the free layer 218 in the first storage element 250. The second storage element 255 may be characterized by a second MTJ dimension D2, which may be substantially similar to the dimension (or diameter) of the free layer 218 in the second storage element 255. The third storage element 260 may be characterized by a third MTJ dimension D3, which may be substantially similar to the dimension (or diameter) of the free layer 218 in the third storage element 260. In some implementations, the first MTJ dimension D1 may be similar to the second MTJ dimension D2. The third MTJ dimension D3 may be greater than either the first MTJ dimension D1 or the second MTJ dimension D2. In some instances, the first MTJ dimension D1 may be between about 20 nm and about 50 nm, the second MTJ dimension D2 may be between about 20 nm and about 55 nm, and the third MTJ dimension D3 may be between about 60 nm and about 85 nm.

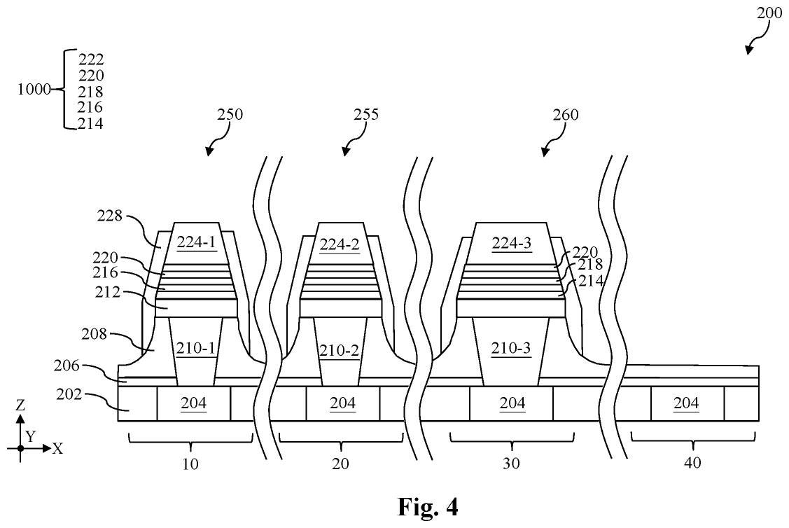

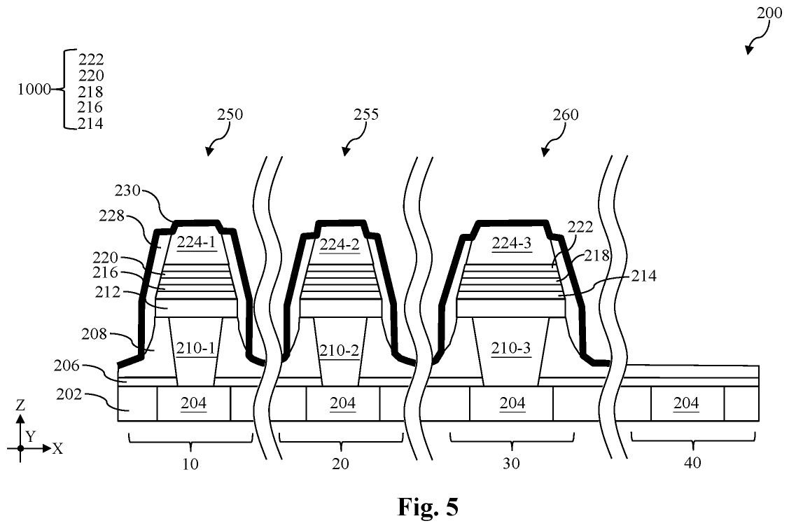

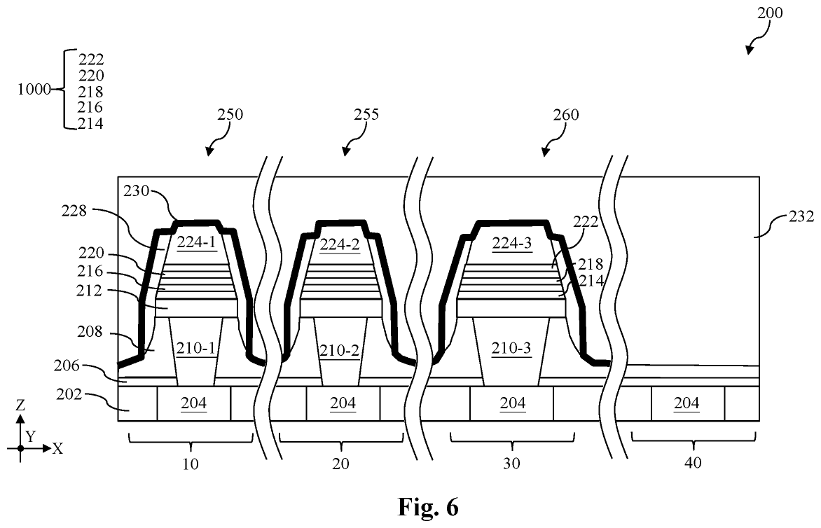

Referring to FIGS. 1, 4, 5, and 6, method 100 includes a block 116 wherein a passivation structure is formed over the first storage element 250, the second storage element 255 and the third storage element 260. The passivation structure may include a spacer layer 228 disposed along sidewalls of the storage elements, an etch stop layer (ESL) 230 over the spacer layer 228, and a third dielectric layer 232 over the ESL 230. While not explicitly shown in the figures, operations at block 116 may include a blanket deposition of the spacer layer 228, etching back the spacer layer 228 to remove the spacer layer 228 on top-facing surfaces (shown in FIG. 4), deposition of the ESL 230 over the spacer layer 228, and deposition of the third dielectric layer 232. In some embodiments, the spacer layer 228 may include silicon nitride, silicon oxide, or a suitable material and may be deposited using CVD or ALD. In one embodiment, the spacer layer 228 may include silicon nitride. The ESL 230 may include aluminum oxide or a metal oxide that is more etch resistant than the spacer layer 228. The ESL 230 may be deposited using CVD or ALD. The third dielectric layer 232 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some instances, the third dielectric layer 232 may be deposited using spin-on coating or FCVD. As shown in FIG. 6, the spacer layer 228 is in physical contact with the second dielectric layer 208, sidewalls of the bottom electrodes 212, the pinned layers 214, the tunnel barrier layer 216, the free layer 218, the maintenance layer 220, and the capping layer 222 of the storage elements over the first region 10, the second region 20 and the third region 30. The ESL 230 is in physical contact with the second dielectric layer 208, the spacer layer 228, and the top electrodes. In some embodiments illustrated in FIG. 5, the ESL 230 is not formed over the fourth region 40 because presence of the ESL 230 over the fourth region 40 may hinder good electrical connection to the conductive feature 204 in the fourth region 40.

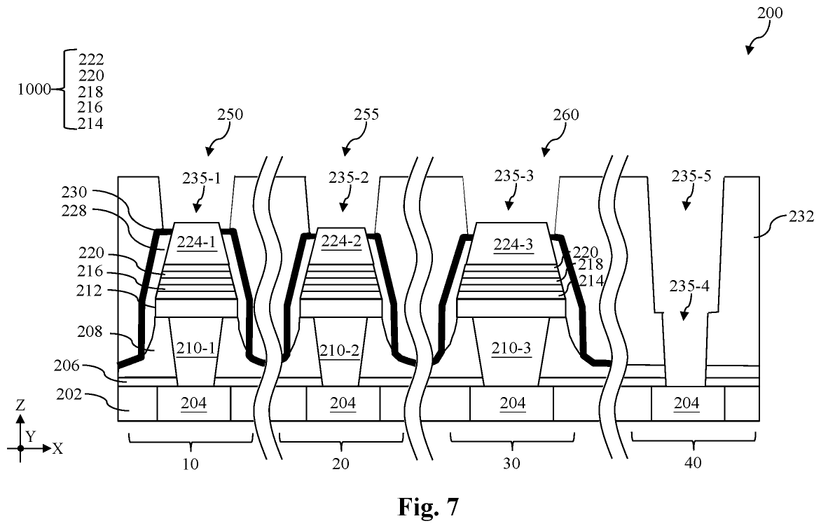

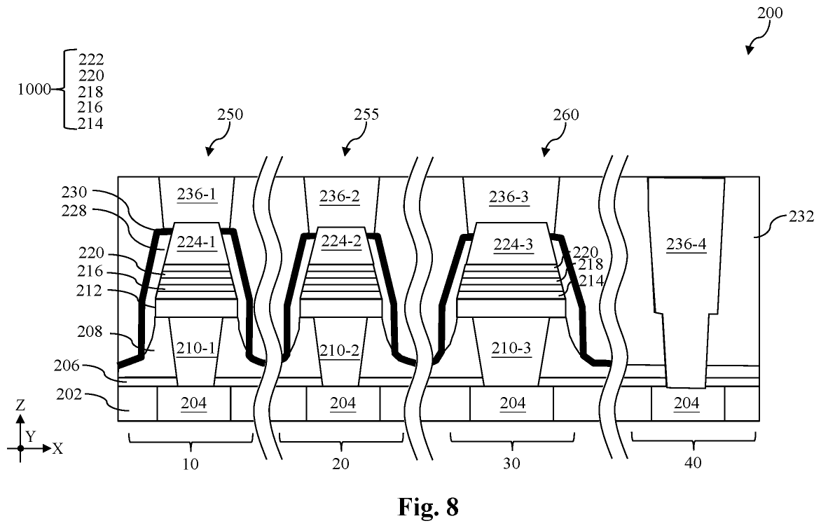

Referring to FIGS. 1, 7 and 8, method 100 includes a block 118 wherein further processes are performed. Such further processes may include formation of a first contact opening 235-1, a second contact opening 235-2, a third contact opening 235-3, a fourth contact opening 235-4, and a fifth contact opening 235-5 (shown in FIG. 7) and deposition of a metal fill layer in the contact openings to form further contact features (as shown in FIG. 8). Photolithography processes and etch processes may be used to form the contact opening. In an example process, The fifth contact opening 235-5 is formed over the fourth region 40 while the first region 10, the second region 20, and the third region 30 are protected by a patterning film, such as a photoresist layer, a bottom antireflective coating (BARC) layer. After the removal of the patterning film, the first contact opening 235-1, the second contact opening 235-2 and the third contact opening 235-3, and the fifth contact opening 235-5 are formed through the third dielectric layer 232, the ESL 230, the second dielectric layer 208, and the buffer layer 206 using photolithography processes and etching processes, as shown in FIG. 7. The conductive feature 204 in the fourth region 40 is exposed in the fourth contact opening 235-4. The first contact opening 235-1 exposes the first top electrode 224-1. The second contact opening 235-2 exposes the second top electrode 224-2. The third contact opening 235-3 exposes the third top electrode 224-3. The fourth contact opening 235-4 and the fifth contact opening 235-5 collectively form a pass-through opening in the fourth region 40 as there is no storage element present in the fourth region 40. The etching at block 118 may include a dry etch process that uses argon (Ar), a fluorine-containing etchant (for example, SF₆, NF₃, CH₂F₂, CHF₃, C₄F₈, and/or C₂F₆), an oxygen-containing etchant, a chlorine-containing etchant (for example, Cl₂, CHCl₃, CCl₄, and/or BCl₃), a bromine-containing etchant (for example, HBr and/or CHBr₃), an iodine-containing etchant, or combinations thereof.

Reference is then made to FIG. 8. A metal fill layer is then deposited over the contact openings using PVD, CVD, electroplating, or electroless plating. The metal fill layer may include ruthenium (Ru), copper (Cu), nickel (Ni), cobalt (Co), or tungsten (W). In one embodiment, the metal fill layer includes copper (Cu). After deposition of the metal fill layer, a planarization process, such as a CMP process, is performed to remove excess metal fill layer over the third dielectric layer 232. After the CMP process, a first top contact via 236-1 is formed over the first storage element 250 to electrically couple to the first top electrode 224-1; a second top contact via 236-2 is formed over the second storage element 255 to electrically couple to the second top electrode 224-2; a third top contact via 236-3 is formed over the third storage element 260 to electrically couple to the third top electrode 224-3, and a fourth top contact via 236-4 is formed to extend through the third dielectric layer 232, the second dielectric layer 208, and the buffer layer 206 to couple to the conductive feature 204 in the fourth region 40. While not explicitly shown, a barrier layer may be deposited over the contact openings before the deposition of the metal fill layer. The barrier layer may include titanium nitride (TiN) or tantalum nitride (TaN). Additionally, method 100 may continue to form further metal layers over the workpiece 200 shown in FIG. 8.

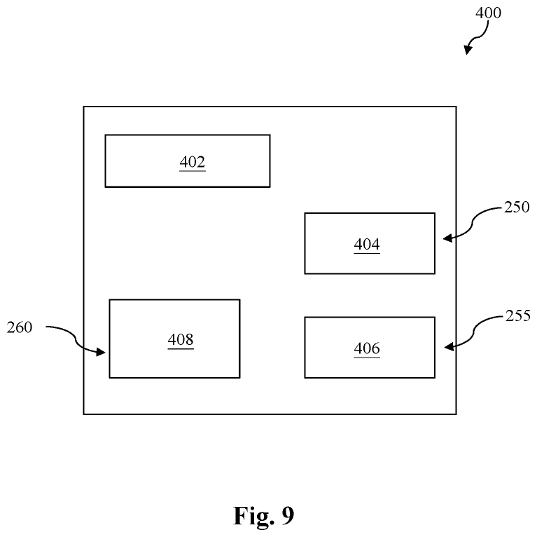

FIG. 9 is a schematic top view of a first integrated circuit (IC) chip 400 that includes a processor region 402, a RAM-like MRAM region 404, an NvMRAM region 406, and an OTP MRAM region 408. The processor region 402 may include core transistors at the FEOL level to form a central processing unit (CPU). The RAM-like MRAM region 404 may correspond to the first region 10 and may include the first storage elements 250 at the BEOL level. The NvMRAM region 406 may correspond to the second region and may include the second storage elements 255 at the BEOL level. The OTP MRAM region 408 may correspond to the third region 30 and may include the third storage element 260 at the BEOL level. As described above, the storage elements in the RAM-like MRAM region 404, the NvMRAM region 406, and the OTP MRAM region 408 may include the same first MTJ stack 1000 and may be formed simultaneously. The first IC chip 400 is suitable for artificial intelligence (AI) applications because it is configured to have short response time. Thermal stability of MRAMs is less a concern for the AI applications. As short response time is sought in the first IC chip 400, the free layer 218 in the first MTJ stack 1000 may be on the thinner side of the spectrum. In some instances, the free layer 218 in the first MTJ stack 1000 may be between about 1.5 nm and about 3.0 nm.

As described above, method 100 may be performed to form the first storage element 250, the second storage element 255 and the third storage element 260 over the first region 10, the second region 20, and the third region 30 of the workpiece 200. Each of the first storage element 250, the second storage element 255 and the third storage element 260 is formed from the same first MTJ stack 1000. The present disclosure also provides a method 500 that forms a fourth storage element 265, the second storage element 255 and the third storage element 260 over the fifth region 50, the second region 20, and the third region 30 of the workpiece 200. Each of the fourth storage element 265, the second storage element 255 and the third storage element 260 is formed from the same second MTJ stack 2000 different from the first MTJ stack 1000. Method 500 is described below in conjunction with fragmentary cross-sectional views of the workpiece 200 in FIGS. 11-17. Method 500 and method 100 may share similar operations and description of a repetitive nature may be intentionally omitted or curtailed for brevity.

Referring to FIGS. 10 and 11, method 500 includes a block 502 where a workpiece 200 is received. Operations at block 502 are similar to those at block 102. For that reason, a detailed description of the operations at block 502 is omitted.

Referring to FIGS. 10 and 11, method 500 includes a block 504 where a buffer layer 206 and a second dielectric layer 208 over the workpiece 200. Operations at block 504 are similar to those at block 104. For that reason, a detailed description of the operations at block 504 is omitted.

Referring to FIGS. 10 and 11, method 500 includes a block 506 where a fourth bottom via 210-4, a second bottom via 210-2 and a third bottom via 210-3 are formed over the fifth region 50, the second region 20, and the third region 30, respectively. Operations at block 506 are similar to those at block 106. For that reason, a detailed description of the operations at block 506 is omitted. It is noted that, the workpiece 200 associated with method 500 includes a fifth region 50 instead of the first region 10. This nomenclature is adopted to indicate that a different storage element—a fourth storage element 265 is formed over the fifth region 50. Similarly, the fourth bottom via 210-4 is used to indicate association with the fourth storage element 265 even though it may share similar dimensions with the first bottom via 210-1, the second bottom via 210-2, or the third bottom via 210-3.

Referring to FIGS. 10 and 11, method 500 includes a block 508 where a bottom electrode layer 212 is deposited over the workpiece 200, including over the second dielectric layer 208, the fourth bottom via 210-4, the second bottom via 210-2, and the third bottom via 210-3. Operations at block 508 are similar to those at block 108. For that reason, a detailed description of the operations at block 508 is omitted.

Referring to FIGS. 10 and 11, method 500 includes a block 510 where a second magnetic tunnel junction (MTJ) stack 2000 is deposited over the bottom electrode layer 212. The second MTJ stack 2000 has a stacking order that is inverse to that of the first MTJ stack 1000. As shown in FIG. 11, the second MTJ stack 2000 includes a capping layer 222 over the bottom electrode layer 212, a maintenance layer 220 over the capping layer 222, a free layer 218 over the maintenance layer 220, a tunnel barrier layer 216 over the free layer 218, and a pinned layer 214 the tunnel barrier layer 216. The pinned layer 214 may include a ferromagnetic material such as cobalt iron (CoFe), cobalt iron boron (CoFeB), or a cobalt-platinum (Co—Pt) alloy. In some alternative embodiments, the pinned layer 214 may include CoFeTa, NiFe, Co, CoFe, CoPt, an alloy of Ni, Co and Fe, platinum manganese (PtMn), iridium manganese (IrMn), rhodium manganese (RhMn), iron manganese (FeMn), or OsMn. The tunnel barrier layer 216 may be formed of a metal oxide selected from a group consisting of magnesium oxide (MgO), titanium oxide (TiO), aluminum titanium oxide (AlTiO), magnesium zinc oxide (MgZnO), aluminum oxide (AlO), zinc oxide (ZnO), zirconium oxide (ZrO), hafnium oxide (HfO), or magnesium tantalum oxide (MgTaO). In one embodiment, the tunnel barrier layer 216 is formed of magnesium oxide. The free layer 218 is formed of a ferromagnetic material and may include cobalt iron boron (CoFeB). The maintenance layer 220 may be formed of a metal oxide selected from a group consisting of magnesium oxide (MgO), titanium oxide (TiO), aluminum titanium oxide (AlTiO), magnesium zinc oxide (MgZnO), aluminum oxide (AlO), zinc oxide (ZnO), zirconium oxide (ZrO), hafnium oxide (HfO), or magnesium tantalum oxide (MgTaO). In one embodiment, the maintenance layer 220 may include magnesium oxide. The capping layer 222 may be optional and may include molybdenum (Mo) or ruthenium (Ru). The pinned layer 214, the tunnel barrier layer 216, the free layer 218, the maintenance layer 220, and the capping layer 222 may each be deposited using PVD, CVD, electro-plating, electro-less plating, or a suitable method. In some embodiments not explicitly shown in the figures, the capping layer 222 may be omitted and the second MTJ stack 2000 may only include the pinned layer 214, the tunnel barrier layer 216, the maintenance layer 220, and the free layer 218.

Referring to FIGS. 10 and 11, method 500 includes a block 512 where a top electrode layer 224 is deposited over the second MTJ stack 2000. Operations at block 512 are similar to those at block 112. For that reason, a detailed description of the operations at block 512 is omitted.

Referring to FIGS. 10, 11 and 12, method 500 includes a block 514 where the top electrode layer 224, the second MTJ stack 2000, and the bottom electrode layer 212 are patterned to form a fourth storage element 265 over the fifth region 50, a second storage element 255 over the second region 20, and a third storage element 260 over the third region 30. At block 514, photolithography processes and etch processes are performed to form the fourth storage element 265, the second storage element 255, and the third storage element 260. In an example process, a hard mask layer 226 is deposited over the workpiece 200, including over the top electrode layer 224. In some embodiments, the hard mask layer 226 may include silicon oxide, silicon nitride, or a combination thereof. In one embodiment, the hard mask layer 226 is formed of silicon oxide (e.g. tetraethylorthosilicate (TEOS) oxide) and may be deposited using spin-on coating or flowable CVD (FCVD). A photoresist layer is then deposited over the hard mask layer 226. The deposited photoresist layer is then exposed to a patterned radiation transmitting through or reflected from a photo mask, baked in a post-exposure bake process, developed in a developer solution, and then rinsed, thereby forming a patterned photoresist layer. As shown in FIG. 11, the patterned photoresist layer is then applied as an etch mask to etch the hard mask layer 226 to form a fourth hard mask pattern 226-4 over the first region 10, a second hard mask pattern 226-2 over the second region 20, and a third hard mask pattern 226-3 over the third region 30. These patterned hard mask patterns are then applied as an etch mask to etch the top electrode layer 224, the second MTJ stack 2000, the bottom electrode layer 212, and the second dielectric layer 208. The etching at block 514 may include an Ion beam etching (IBE) 300. When it comes to patterning of MTJ stacks, IBE may be more desirable than reactive ion etching (RIE) because IBE is less likely to introduce chemical impurities into the MTJ stack. Impurities may deteriorate performance of the storage element. The IBE 300 may use one or more noble gas ions such as Ar, Kr, Xe, and Ne generated with an RF or DC power. It should be understood that IBE typically includes rotating the workpiece 200.

In order to form memory devices with different device properties, the storage elements have different dimensions. It is observed that, given an identical MTJ stack, a storage element with a larger free layer exhibit better thermal stability than a storage element having a smaller free layer. Additionally, a storage element having a smaller free layer provides faster response time than a storage element having a larger free layer. In some embodiments where a storage elements has a circular shape when viewed along a vertical direction, a critical dimension (CD) of the storage element may refer to a diameter of the free layer. In some embodiments represented in FIG. 11, hard mask patterns of different dimensions are implemented to achieve different storage element diameters (or dimensions). As shown in FIG. 11, the fourth hard mask pattern 226-4 has a fourth dimension d4, the second hard mask pattern 226-2 has a second dimension d2, and the third hard mask pattern 226-3 has a third dimension d3. The fourth dimension d4 is greater than the second dimension d2 or the third dimension d3. The third dimension d3 is greater than either the second dimension d2.

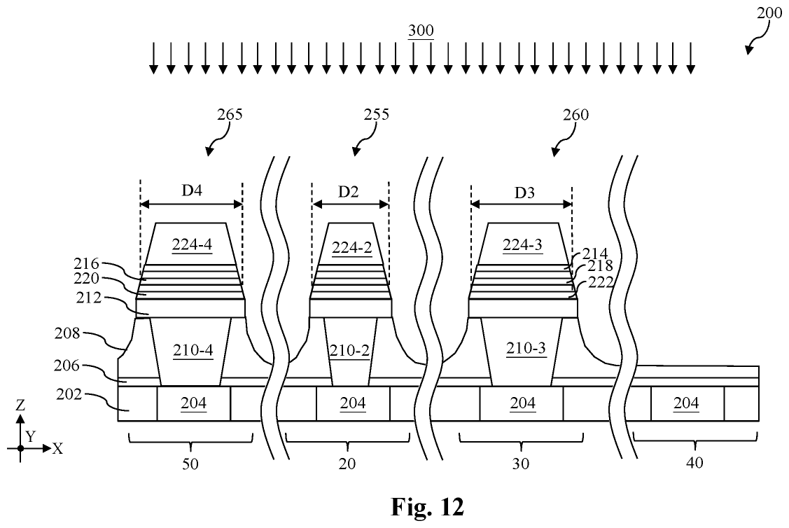

As shown in FIG. 12, the IBE 300 may result in tapered sidewalls such that each of the fourth storage element 265, the second storage element 255, and the third storage element 260 has a smaller top electrode dimension and a larger bottom element dimension. The fourth storage element 265 includes the fourth top electrode 224-4 formed from the top electrode layer 224. The second storage element 255 includes the second top electrode 224-2 formed from the top electrode layer 224. The third storage element 260 includes the third top electrode 224-3 formed from the top electrode layer 224. In some embodiments, the fourth storage element 265 may be characterized by a fourth MTJ dimension Dd, which may be substantially similar to the dimension (or diameter) of the free layer 218 in the fourth storage element 265. The second storage element 255 may be characterized by a second MTJ dimension D2, which may be substantially similar to the dimension (or diameter) of the free layer 218 in the second storage element 255. The third storage element 260 may be characterized by a third MTJ dimension D3, which may be substantially similar to the dimension (or diameter) of the free layer 218 in the third storage element 260. In some implementations, the fourth MTJ dimension D4 is greater than the second MTJ dimension D2 or the third MTJ dimension D3. The third MTJ dimension D3 may be greater than the second MTJ dimension D2. In some instances, the fourth MTJ dimension D4 may be between about 75 nm and about 100 nm, the second MTJ dimension D2 may be between about 20 nm and about 55 nm, and the third MTJ dimension D3 may be between about 60 nm and about 85 nm.

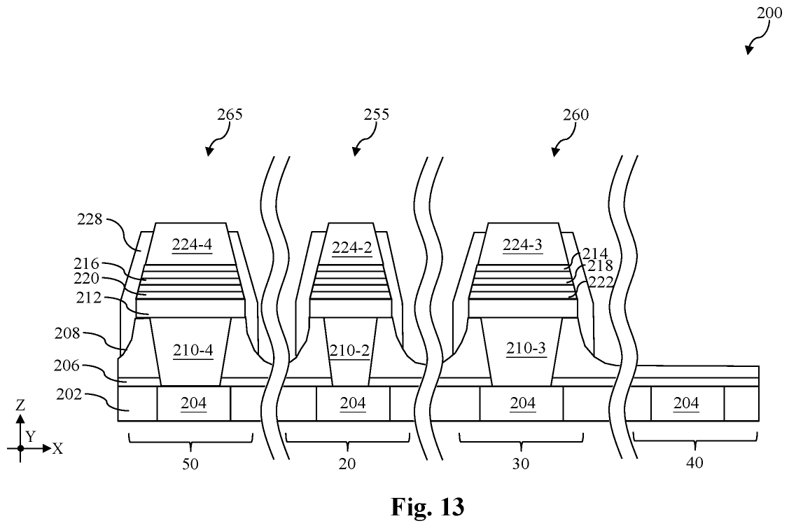

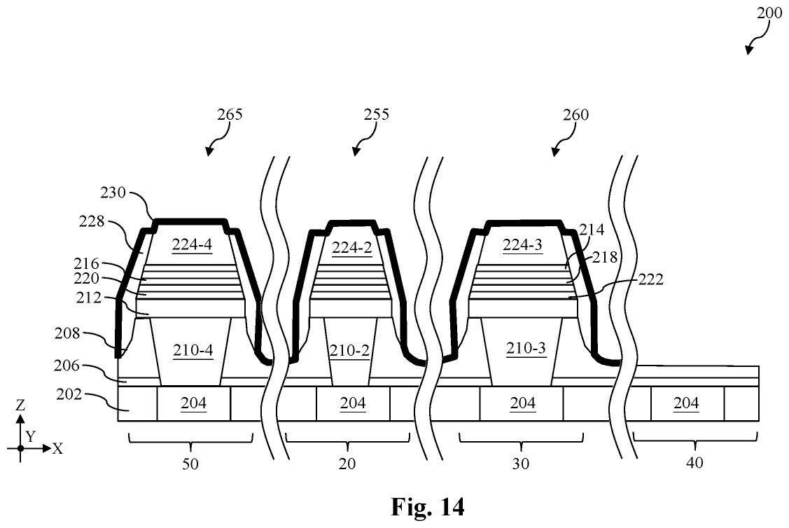

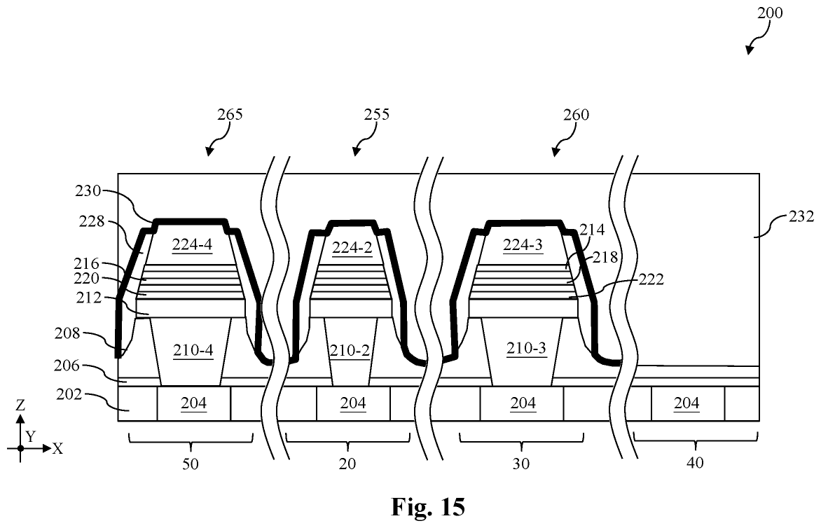

Referring to FIGS. 10, 13, 14, and 15, method 500 includes a block 516 wherein a passivation structure is formed over the fourth storage element 265, the second storage element 255 and the third storage element 260. The passivation structure may include a spacer layer 228 disposed along sidewalls of the storage elements, an etch stop layer (ESL) 230 over the spacer layer 228, and a third dielectric layer 232 over the ESL 230. While not explicitly shown in the figures, operations at block 516 may include a blanket deposition of the spacer layer 228, etching back the spacer layer 228 to remove the spacer layer 228 on top-facing surfaces (shown in FIG. 13), deposition of the ESL 230 over the spacer layer 228 (shown in FIG. 14), and deposition of the third dielectric layer 232 (shown in FIG. 15). In some embodiments, the spacer layer 228 may include silicon nitride, silicon oxide, or a suitable material and may be deposited using CVD or ALD. In one embodiment, the spacer layer 228 may include silicon nitride. The ESL 230 may include aluminum oxide or a metal oxide that is more etch resistant than the spacer layer 228. The ESL 230 may be deposited using CVD or ALD. The third dielectric layer 232 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some instances, the third dielectric layer 232 may be deposited using spin-on coating or FCVD. As shown in FIG. 15, the spacer layer 228 is in physical contact with the second dielectric layer 208, sidewalls of the bottom electrodes 212, the pinned layers 214, the tunnel barrier layer 216, the free layer 218, the maintenance layer 220, and the capping layer 222 of the storage elements over the fourth region 40, the second region 20 and the third region 30. The ESL 230 is in physical contact with the second dielectric layer 208, the spacer layer 228, and the top electrodes. In some embodiments illustrated in FIG. 14, the ESL 230 is not formed over the fourth region 40 because presence of the ESL 230 over the fourth region 40 may hinder good electrical connection to the conductive feature 204 in the fourth region 40.

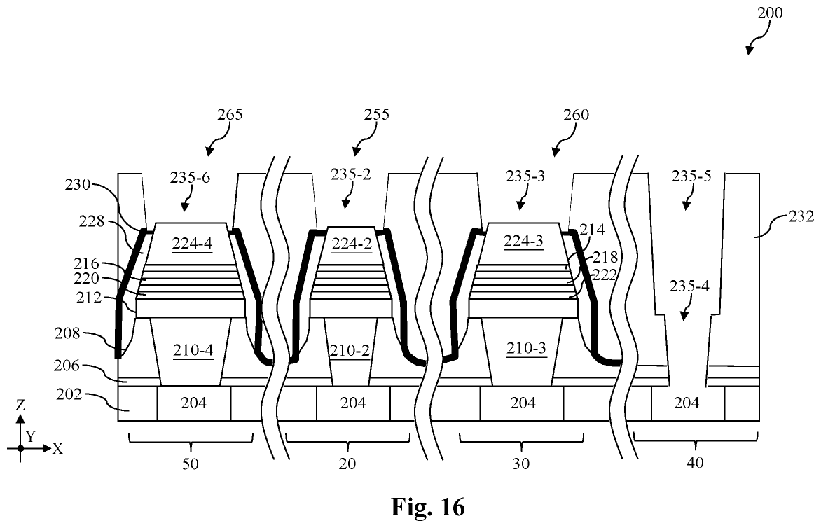

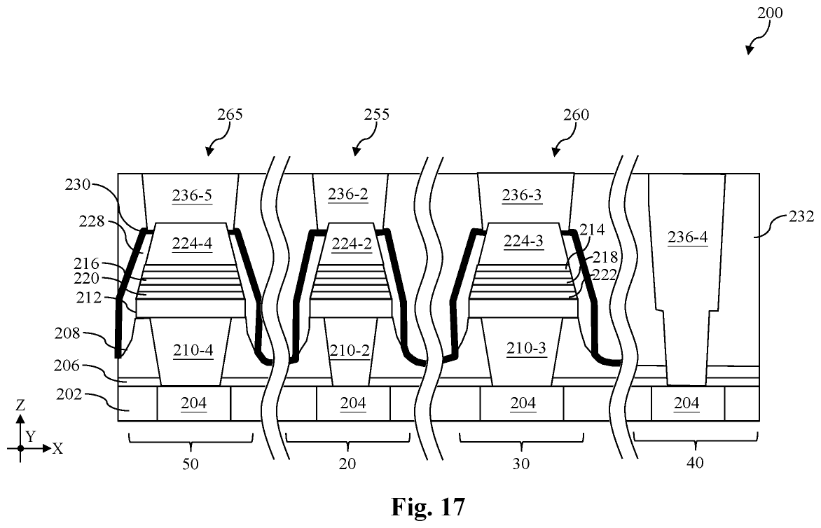

Referring to FIGS. 10, 16 and 17, method 500 includes a block 518 wherein further processes are performed. Such further processes may include formation of a sixth contact opening 235-6, a second contact opening 235-2, a third contact opening 235-3, a fourth contact opening 235-4, and a fifth contact opening 235-5 (shown in FIG. 16) and deposition of a metal fill layer in the contact openings to form further contact features (as shown in FIG. 17). Photolithography processes and etch processes may be used to form the contact opening. In an example process, The fifth contact opening 235-5 is formed over the fourth region 40 while the fifth region 50, the second region 20, and the third region 30 are protected by a patterning film, such as a photoresist layer, a bottom antireflective coating (BARC) layer. After the removal of the patterning film, the sixth contact opening 235-6, the second contact opening 235-2, the third contact opening 235-3, and the fifth contact opening 235-5 are formed through the third dielectric layer 232, the ESL 230, the second dielectric layer 208, and the buffer layer 206 using photolithography processes and etching processes, as shown in FIG. 16. The conductive feature 204 in the fourth region 40 is exposed in the fourth contact opening 235-4. The sixth contact opening 235-6 exposes the fourth top electrode 224-4.

The second contact opening 235-2 exposes the second top electrode 224-2. The third contact opening 235-3 exposes the third top electrode 224-3. The fourth contact opening 235-4 and the fifth contact opening 235-5 collectively form a pass-through opening in the fourth region 40 as there is no storage element present in the fourth region 40. The etching at block 518 may include a dry etch process that uses argon (Ar), a fluorine-containing etchant (for example, SF₆, NF₃, CH₂F₂, CHF₃, C₄F₈, and/or C₂F₆), an oxygen-containing etchant, a chlorine-containing etchant (for example, Cl₂, CHCl₃, CCl₄, and/or BCl₃), a bromine-containing etchant (for example, HBr and/or CHBr₃), an iodine-containing etchant, or combinations thereof.

Reference is then made to FIG. 17. A metal fill layer is then deposited over the contact openings using PVD, CVD, electroplating, or electroless plating. The metal fill layer may include ruthenium (Ru), copper (Cu), nickel (Ni), cobalt (Co), or tungsten (W). In one embodiment, the metal fill layer includes copper (Cu). After deposition of the metal fill layer, a planarization process, such as a CMP process, is performed to remove excess metal fill layer over the third dielectric layer 232. After the CMP process, a fifth top contact via 236-5 is formed over the fourth storage element 265 to electrically couple to the fourth top electrode 224-4; a second top contact via 236-2 is formed over the second storage element 255 to electrically couple to the second top electrode 224-2; a third top contact via 236-3 is formed over the third storage element 260 to electrically couple to the third top electrode 224-3, and a fourth top contact via 236-4 is formed to extend through the third dielectric layer 232, the second dielectric layer 208, and the buffer layer 206 to couple to the conductive feature 204 in the fourth region 40. While not explicitly shown, a barrier layer may be deposited over the contact openings before the deposition of the metal fill layer. The barrier layer may include titanium nitride (TiN) or tantalum nitride (TaN). Additionally, method 500 may continue to form further metal layers over the workpiece 200 shown in FIG. 17.

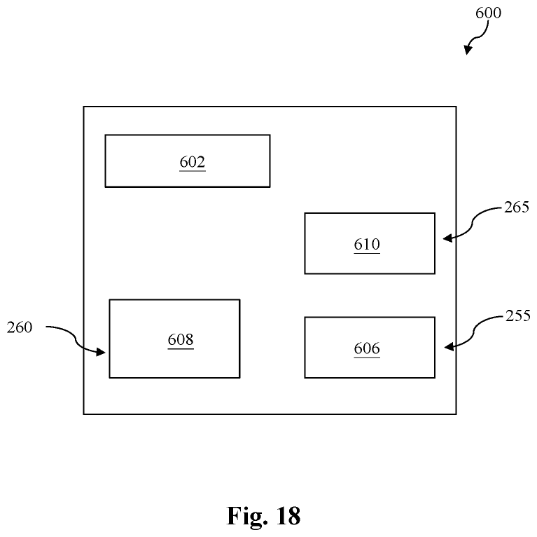

FIG. 18 is a schematic top view of a second integrated circuit (IC) chip 600 that includes a processor region 602, a reflow MRAM region 610, an NvMRAM region 606, and an OTP MRAM region 608. The processor region 602 may include core transistors at the FEOL level to form a central processing unit (CPU). The reflow MRAM region 610 may correspond to the fifth region 50 and may include the fourth storage elements 265 at the BEOL level. The NvMRAM region 606 may correspond to the second region 20 and may include the second storage elements 255 at the BEOL level. The OTP MRAM region 608 may correspond to the third region 30 and may include the third storage element 260 at the BEOL level. As described above, the storage elements in the Reflow MRAM region 610, the NvMRAM region 606, and the OTP MRAM region 608 may include the same second MTJ stack 2000 and may be formed simultaneously. The second IC chip 600 is suitable for micro-controller unit (MCU) applications because it is configured to have good thermal stability and retain memory for a long time. Short response time is less a concern for the MCU applications. As thermal stability is sought in the second IC chip 600, the free layer 218 in the second MTJ stack 2000 may be on the thicker side of the spectrum. In some instances, the free layer 218 in the second MTJ stack 2000 may be between about 2.0 nm and about 3.5 nm.

In one exemplary aspect, the present disclosure is directed to a semiconductor device. The semiconductor device includes a first conductive feature and a second conductive feature disposed in a first dielectric layer, a buffer layer disposed over the first dielectric layer, a second dielectric layer disposed over the buffer layer, a first bottom via extending through the buffer layer and the second dielectric layer to couple to the first conductive feature along a first direction, a second bottom via extending through the buffer layer and the second dielectric layer to couple to the second conductive feature along the first direction, a first bottom electrode disposed on the first bottom via, a second bottom electrode disposed on the second bottom via, a first magnetic tunnel junction (MTJ) stack over the first bottom electrode, and a second MTJ stack over the second bottom electrode. The first MTJ stack and the second MTJ stack have a same thickness along the first direction. The first MTJ stack has a first width along a second direction perpendicular to the first direction and the second MTJ stack has a second width along the second direction. The second width is greater than the first width.

In some embodiments, the first MTJ stack includes a pinned layer over the first bottom electrode, a tunnel barrier layer over the pinned layer, and a free layer over the tunnel barrier layer. In some embodiments, the pinned layer includes cobalt, iron, boron, or platinum, the tunnel barrier layer includes magnesium oxide, and the free layer includes cobalt, iron, or boron. In some instances, the first MTJ stack further includes a maintenance layer over the free layer and a capping layer over the maintenance layer. In some implementations, the maintenance layer includes magnesium oxide and the capping layer includes molybdenum or ruthenium. In some embodiments, the first width is between about 20 nm and about 55 nm and the second width is between about 75 nm and about 100 nm. In some embodiments, the buffer layer includes silicon carbide. In some embodiments, the first dielectric layer includes silicon-rich silicon oxide.

In another exemplary aspect, the present disclosure is directed to a semiconductor device. The semiconductor device includes a first memory structure and a second memory structure. The first memory structure includes a first bottom electrode, a first top electrode over the first bottom electrode, and a first magnetic tunnel junction (MTJ) stack sandwiched between the first bottom electrode and the first top electrode along a first direction. The second memory structure includes a second bottom electrode, a second top electrode over the second bottom electrode, and a second MTJ stack sandwiched between the first bottom electrode and the first top electrode along the first direction. The first MTJ stack has a first width along a second direction perpendicular to the first direction and the second MTJ stack has a second width along the second direction. The second width is greater than the first width.

In some embodiments, the first MTJ stack and the second MTJ stack have a same thickness along the first direction. In some implementations, the first bottom electrode, the first top electrode, the second bottom electrode, and the second top electrode include titanium nitride, tantalum nitride, or a combination thereof. In some embodiments, the first MTJ stack includes a capping layer over the first bottom electrode, a maintenance layer over the capping layer, a free layer over the maintenance layer, a tunnel barrier layer over the free layer, and a pinned layer over the tunnel barrier layer. In some embodiments, the capping layer includes molybdenum or ruthenium, the maintenance layer includes magnesium oxide, the free layer includes cobalt, iron, or boron, the tunnel barrier layer includes magnesium oxide, and the pinned layer includes cobalt, iron, boron, or platinum. In some instances, the semiconductor device further includes a third memory structure that includes a third bottom electrode and a third top electrode over the third bottom electrode. The semiconductor device also includes a third (MTJ) stack sandwiched between the third bottom electrode and the third top electrode along the first direction. The third MTJ stack includes a third width along the second direction. The third width is greater than the first width. In some embodiments, the first width is between about 20 nm and about 55 nm, the second width is between about 80 nm and about 100 nm, and the third width is between about 75 nm and about 100 nm.

In yet another exemplary aspect, the present disclosure is directed to a method. The method includes receiving a workpiece that includes a first conductive feature and a second conductive feature disposed in a first dielectric layer, a second dielectric layer over the first dielectric layer, a first bottom via extending through the second dielectric layer to couple to the first conductive feature along a first direction, and a second bottom via extending through the second dielectric layer to couple to the second conductive feature along the first direction. The method further includes depositing a bottom electrode layer over the first bottom via, the second bottom via and the second dielectric layer, depositing a magnetic tunnel junction (MTJ) stack over the bottom electrode layer, depositing a top electrode layer over the MTJ stack, depositing a hard mask layer over the top electrode layer, patterned the hard mask layer to form a first hard mask pattern directly over the first bottom via and a second hard mask pattern directly over the second bottom via, and etching the top electrode layer, the MTJ stack, and the bottom electrode layer using the first hard mask pattern and the second hard mask pattern as an etch mask to form a first memory structure directly over the first bottom via and a second memory structure directly over the second bottom via. The first hard mask pattern includes a first width along a second direction perpendicular to the first direction and the second hard mask pattern includes a second width along the second direction. The second width is greater than the first width.

In some embodiments, the etching includes use of ion beam etching (IBE). In some instances, the first memory structure includes a first bottom electrode formed from the bottom electrode layer, the second memory structure includes a second bottom electrode formed from the bottom electrode layer, the first bottom electrode includes a third width along the second direction and the second bottom electrode includes a fourth width along the second direction. The fourth width is greater than the third width. In some embodiments, the method may further include after the etching, depositing a spacer layer over the first memory structure and the second memory structure, etching back the spacer layer, after the etching back, depositing an etch stop layer over the spacer layer, the first memory structure and the second memory structure, and depositing a third dielectric layer over the etch stop layer. In some embodiments, the etch stop layer includes aluminum oxide.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first conductive feature and a second conductive feature disposed in a first dielectric layer;
a buffer layer disposed over the first dielectric layer;
a second dielectric layer disposed over the buffer layer;
a first bottom via extending through the buffer layer and the second dielectric layer to couple to the first conductive feature along a first direction;
a second bottom via extending through the buffer layer and the second dielectric layer to couple to the second conductive feature along the first direction;
a first bottom electrode disposed on the first bottom via;
a second bottom electrode disposed on the second bottom via;
a first magnetic tunnel junction (MTJ) stack over the first bottom electrode; and
a second MTJ stack over the second bottom electrode,
wherein the first MTJ stack and the second MTJ stack have a same thickness along the first direction,
wherein the first MTJ stack has a first width along a second direction perpendicular to the first direction and the second MTJ stack has a second width along the second direction,
wherein the second width is greater than the first width.

2. The semiconductor device of claim 1, wherein the first MTJ stack comprises:
a pinned layer over the first bottom electrode;
a tunnel barrier layer over the pinned layer; and
a free layer over the tunnel barrier layer.

3. The semiconductor device of claim 2,
wherein the pinned layer comprises cobalt, iron, boron, or platinum,
wherein the tunnel barrier layer comprises magnesium oxide,
wherein the free layer comprises cobalt, iron, or boron.

4. The semiconductor device of claim 2, wherein the first MTJ stack further comprises:
a maintenance layer over the free layer; and
a capping layer over the maintenance layer.

5. The semiconductor device of claim 4,
wherein the maintenance layer comprises magnesium oxide,
wherein the capping layer comprises molybdenum or ruthenium.

6. The semiconductor device of claim 1,
wherein the first width is between about 20 nm and about 55 nm,
wherein the second width is between about 75 nm and about 100 nm.

7. The semiconductor device of claim 1, wherein the buffer layer comprises silicon carbide.

8. The semiconductor device of claim 1, wherein the first dielectric layer comprises silicon-rich silicon oxide.

9. A semiconductor device, comprising:
a first memory structure comprising:
a first bottom electrode,
a first top electrode over the first bottom electrode, and
a first magnetic tunnel junction (MTJ) stack sandwiched between the first bottom electrode and the first top electrode along a first direction; and
a second memory structure comprising:
a second bottom electrode,
a second top electrode over the second bottom electrode, and
a second MTJ stack sandwiched between the first bottom electrode and the first top electrode along the first direction,
wherein the first MTJ stack has a first width along a second direction perpendicular to the first direction and the second MTJ stack has a second width along the second direction,
wherein the second width is greater than the first width.

10. The semiconductor device of claim 9, wherein the first MTJ stack and the second MTJ stack have a same thickness along the first direction.

11. The semiconductor device of claim 9, wherein the first bottom electrode, the first top electrode, the second bottom electrode, and the second top electrode comprise titanium nitride, tantalum nitride, or a combination thereof

12. The semiconductor device of claim 9, wherein the first MTJ stack comprises:
a capping layer over the first bottom electrode;
a maintenance layer over the capping layer;
a free layer over the maintenance layer;
a tunnel barrier layer over the free layer; and
a pinned layer over the tunnel barrier layer.

13. The semiconductor device of claim 12,
wherein the capping layer comprises molybdenum or ruthenium,
wherein the maintenance layer comprises magnesium oxide,
wherein the free layer comprises cobalt, iron, or boron,
wherein the tunnel barrier layer comprises magnesium oxide,
wherein the pinned layer comprises cobalt, iron, boron, or platinum.

14. The semiconductor device of claim 9, further comprising:
a third memory structure comprising:
a third bottom electrode,
a third top electrode over the third bottom electrode, and
a third (MTJ) stack sandwiched between the third bottom electrode and the third top electrode along the first direction,
wherein the third MTJ stack comprises a third width along the second direction,
wherein the third width is greater than the first width.

15. The semiconductor device of claim 14,
wherein the first width is between about 20 nm and about 55 nm,
wherein the second width is between about 80 nm and about 100 nm,
wherein the third width is between about 75 nm and about 100 nm.

16. A method, comprising:
receiving a workpiece comprising:
a first conductive feature and a second conductive feature disposed in a first dielectric layer,
a second dielectric layer over the first dielectric layer,
a first bottom via extending through the second dielectric layer to couple to the first conductive feature along a first direction, and
a second bottom via extending through the second dielectric layer to couple to the second conductive feature along the first direction;
depositing a bottom electrode layer over the first bottom via, the second bottom via and the second dielectric layer;
depositing a magnetic tunnel junction(MTJ) stack over the bottom electrode layer;
depositing a top electrode layer over the MTJ stack;
depositing a hard mask layer over the top electrode layer;
patterned the hard mask layer to form a first hard mask pattern directly over the first bottom via and a second hard mask pattern directly over the second bottom via; and
etching the top electrode layer, the MTJ stack, and the bottom electrode layer using the first hard mask pattern and the second hard mask pattern as an etch mask to form a first memory structure directly over the first bottom via and a second memory structure directly over the second bottom via,
wherein the first hard mask pattern comprises a first width along a second direction perpendicular to the first direction and the second hard mask pattern comprises a second width along the second direction,
wherein the second width is greater than the first width.

17. The method of claim 16, wherein the etching comprises use of ion beam etching (IBE).

18. The method of claim 16,
wherein the first memory structure comprises a first bottom electrode formed from the bottom electrode layer,
wherein the second memory structure comprises a second bottom electrode formed from the bottom electrode layer,
wherein the first bottom electrode comprises a third width along the second direction and the second bottom electrode comprises a fourth width along the second direction,
wherein fourth width is greater than the third width.

19. The method of claim 16, further comprising:
after the etching, depositing a spacer layer over the first memory structure and the second memory structure;
etching back the spacer layer;
after the etching back, depositing an etch stop layer over the spacer layer, the first memory structure and the second memory structure; and
depositing a third dielectric layer over the etch stop layer.

20. The method of claim 19, wherein the etch stop layer comprises aluminum oxide.
